(19) United States
(12) Patent Application Publication
(10) Pub. No.: US 2021/0408505 A1
(43) Pub. Date: Dec. 30, 2021

(54) SUB-PIXEL STRUCTURE, ORGANIC LIGHT EMITTING DIODE DISPLAY PANEL, AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Wenliang Gong, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/623,532

(22) PCT Filed: Sep. 30, 2019
(86) PCT No.: PCT/CN2019/109511

§ 371 Date: Dec. 17, 2019

(30) Foreign Application Priority Data
Aug. 20, 2019 (CN) 201910770562.7

(51) Int. Cl. H01L 51/56; H01L 51/52; H01L 27/32

(52) U.S. Cl. CPC H01L 51/56; H01L 51/5284; H01L 27/322; H01L 27/3218; H01L 51/5237

(57) ABSTRACT

A sub-pixel structure, an organic light emitting diode display panel, and a manufacturing method thereof, the sub-pixel structure including an encapsulating sub-pixel structure, and a color film disposed on a light emitting surface of the encapsulating sub-pixel structure, wherein the color film has a hemispherical shape, to reduce a thickness of the OLED display panel, enhance light extraction rate, and prevent negative influence of exposure, development, and post-baking processes in color film manufacturing process, as well as being able to effectively reduce a reflectance of the organic light emitting diode display panel under strong light without disposing a polarizer.

### FIELD OF INVENTION

The present disclosure relates to the field of display technologies, and more particularly, to a sub-pixel structure, an organic light emitting diode display panel, and a manufacturing method thereof.

### BACKGROUND OF INVENTION

In the prior art, in order to fulfill the operational requirements of an organic light emitting diode (OLED) display panel, a polarizer is often provided to reduce reflectance of the display panel under strong light.

The polarizer can reduce the reflectance of the display panel under strong light, however, a large amount of light from the OLED display panel is also lost, which greatly increases the loading and reduces the lifespan of the OLED display panel. On the other hand, a thickness of the polarizer is greater and material is brittle, which is not conducive to the development of dynamic bending products.

Therefore, there is a need to provide a sub-pixel structure, an organic light emitting diode display panel, and a manufacturing method thereof to solve the problems of the prior art.

### SUMMARY OF INVENTION

In order to solve the above problems, the present disclosure provides a sub-pixel structure, an organic light emitting diode display panel, and a manufacturing method thereof, which can reduce a thickness of the OLED display panel, enhance the light extraction rate, avoid the negative influence of the exposure, development, and post-baking processes in the color film manufacturing process, and can effectively reduce a reflectance of the organic light emitting diode display panel under the strong light without disposing the polarizer.

In order to achieve the above objects, the present disclosure provides a sub-pixel structure, including an encapsulating sub-pixel structure; and a color film disposed on a light-emitting surface of the encapsulating sub-pixel structure, wherein the color film has a hemispherical shape.

In an embodiment of the present disclosure, the sub-pixel structure further comprising a black matrix disposed on other portions of the light-emitting surface of the encapsulating sub-pixel structure where the color film is not disposed.

In an embodiment of the present disclosure, the color film is a pigment-added hemispherical polymer.

In an embodiment of the present disclosure, the encapsulating sub-pixel structure is internally provided with a light-emitting layer, and a contact surface of the color film with the encapsulating sub-pixel structure is larger than a top surface of the light-emitting layer.

In an embodiment of the present disclosure, the encapsulating sub-pixel structure is internally provided with a light-emitting layer, and a left edge of the color film and a right edge of the color film are aligned with a left edge of the light-emitting layer and a right edge of the light-emitting layer, respectively.

In an embodiment of the present disclosure, the color film comprises an ink layer.

In order to achieve the above objects, the present disclosure further provides an organic light emitting diode display panel, comprising:

an encapsulating organic light emitting diode display panel, wherein the encapsulating organic light emitting diode panel comprises a red sub-pixel structure, a green sub-pixel structure and a blue sub-pixel structure;

a red color film disposed on a light emitting surface of the red sub-pixel structure, wherein the red color film has a hemispherical shape;

a green color film disposed on a light emitting surface of the green sub-pixel structure, wherein the green color film has a hemispherical shape; and

a blue color film disposed on a light emitting surface of the blue sub-pixel structure, and the blue color film has a hemispherical shape.

In an embodiment of the present disclosure, the red sub-pixel structure comprises a red luminescent layer configured to emit red light, the green sub-pixel structure comprises a green luminescent layer configured to emit green light, and the blue sub-pixel structure comprises a blue luminescent layer configured to emit blue light.

In an embodiment of the present disclosure, a position of the red color film is aligned with a position of the red luminescent layer, a position of the green color film is aligned with a position of the green luminescent layer, and a position of the blue color film is aligned with a position of the blue light emitting layer.

In an embodiment of the present disclosure, a contact surface of the red color film with the encapsulating organic light emitting diode display panel is larger than a top surface of the red luminescent layer.

In an embodiment of the present disclosure, a contact surface of the green color film with the encapsulating organic light emitting diode display panel is larger than a top surface of the green luminescent layer.

In an embodiment of the present disclosure, a contact surface of the blue color film with the encapsulating organic light emitting diode display panel is larger than a top surface of the blue luminescent layer.

In an embodiment of the present disclosure, the red color film, the green color film, and the blue color film are respectively a pigment-added hemispherical polymer.

In an embodiment of the present disclosure, the organic light emitting diode display panel further comprising a black matrix disposed on other portions of the light-emitting surface of the encapsulating organic light emitting diode display panel where the red color film, the green color film, and the blue color film are not disposed.

In an embodiment of the present disclosure, the red color film comprises a red ink layer, the green color film comprises a green ink layer, and the blue color film comprises a green ink layer.

In an embodiment of the present disclosure, the black matrix comprises a black ink layer.

In order to achieve the above objects, a method of manufacturing an organic light emitting diode display panel, comprising:

providing an encapsulating organic light emitting diode display panel comprising a red sub-pixel structure, a green sub-pixel structure, and a blue sub-pixel structure;

forming a red color film having a hemispherical shape on the light emitting surface of the red sub-pixel structure;

forming a green color film having a hemispherical shape on the light emitting surface of the green sub-pixel structure; and

forming a blue color film having a hemispherical shape on the light emitting surface of the blue sub-pixel structure.

In an embodiment of the present disclosure, after forming the red color film, the green color film, and the blue color film, forming a black matrix on other portions of the light-emitting surface of the encapsulating organic light emitting diode display panel where the red color film, the green color film, and the blue color film are not disposed.

In an embodiment of the present disclosure, the red color film, the green color film, and the blue color film are disposed on the light-emitting surface of the red sub-pixel structure, the light-emitting surface of the green sub-pixel structure, and the light-emitting surface of the blue sub-pixel structure, respectively, by inkjet printing.

In an embodiment of the present disclosure, the black matrix is disposed on other portions of the light-emitting surface of the encapsulating organic light emitting diode display panel where the red color film, the green color film, and the blue color film are not disposed by inkjet printing.

Compared with the prior art, the present disclosure provides a sub-pixel structure, an organic light emitting diode display panel, and a manufacturing method thereof, the sub-pixel structure including an encapsulating sub-pixel structure, and a color film disposed on a light-emitting surface of the encapsulating sub-pixel structure, wherein the color film has a hemispherical shape, to reduce a thickness of the OLED display panel, enhance the light extraction rate, and prevent the negative influence of the exposure, development, and post-baking processes in the color film manufacturing process, as well as being able to effectively reduce a reflectance of the organic light emitting diode display panel under strong light without disposing a polarizer.

### DESCRIPTION OF DRAWINGS

FIG. 1 is a block diagram showing an encapsulating sub-pixel structure according to an embodiment of the present disclosure.

FIG. 2 is a block diagram showing a sub-pixel structure according to an embodiment of the present disclosure.

FIG. 3 is a block diagram showing a sub-pixel structure according to an embodiment of the present disclosure.

FIG. 4 is a block diagram showing an encapsulating organic light emitting diode display panel according to an embodiment of the present disclosure.

FIG. 5 is a block diagram showing an organic light emitting diode display panel according to an embodiment of the present disclosure.

FIG. 6 is a block diagram showing an organic light emitting diode display panel according to an embodiment of the present disclosure.

FIG. 7 is a flowchart showing a method of manufacturing an organic light emitting diode display panel according to an embodiment of the present disclosure.

### DETAILED DESCRIPTION OF PREFERRED EMBODIMENTS

The following description of the various embodiments is provided to illustrate the specific embodiments. Directional terms described by the present disclosure, such as top, bottom, front, back, left, right, inner, outer, side, etc., are only directions by referring to the accompanying drawings, and thus the used terms are used only for the purpose of describing embodiments of the present disclosure and are not intended to be limiting of the present disclosure.

In the figures, units with similar structures are labeled with the same reference number.

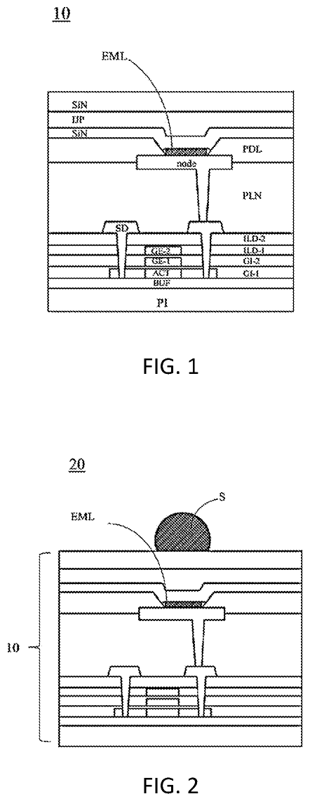

Please refer to FIG. 1, which is a block diagram showing an encapsulating sub-pixel structure according to an embodiment of the present disclosure. In the embodiment of FIG. 1, the encapsulating sub-pixel structure 10 includes a substrate PI, a buffer layer BUF disposed on the substrate PI, an active layer ACT disposed on the buffer layer BUF, and a first gate layer GE-1 disposed on the active layer ACT, a second gate layer GE-2 disposed on the first gate layer GE-1, a first gate dielectric layer GI-1 disposed on the buffer layer BUF, a second gate dielectric layer GI-2 disposed on the first gate dielectric layer GI-1, a first interlayer insulating layer ILD-1 disposed on the second gate dielectric layer GI-2, a second interlayer insulating layer ILD-2 disposed on the first interlayer insulating layer ILD-1, a planarization layer PLN disposed on the second interlayer insulating layer ILD-2, a pixel defining layer PDL disposed on the planarization layer PLN, and a silicon nitride layer SiN disposed on the pixel defining layer PDL, an inkjet printing layer IJP disposed on the silicon nitride layer SiN, an electrode node disposed between the pixel defining layer PDL and the planarization layer PLN, and a light emitting layer EML disposed on the electrode node. The encapsulating sub-pixel structure 10 disclosed in FIG. 1 is an embodiment of the encapsulating sub-pixel structure, however, the encapsulating sub-pixel structure of the present disclosure is not limited thereto.

Please refer to FIG. 2, which shows a block diagram showing a sub-pixel structure according to an embodiment of the present disclosure. The sub-pixel structure 20 includes an encapsulating sub-pixel structure 10, and a color film S disposed on a light-emitting surface of the encapsulating sub-pixel structure 10, wherein the color film S has a hemispherical shape, forming an antireflection effect of the lens. The inside of the encapsulating sub-pixel structure 10 is further provided with a light emitting layer EML. By disposing the color film S and the sub-pixel structure 20, it is possible to effectively reduce the reflectance under strong light and improve the light extraction rate without disposing a polarizer.

In an embodiment of the present disclosure, the color film S is a pigment-added hemispherical polymer.

In an embodiment of the present disclosure, a position of the color film S is aligned with a set position of the light emitting layer EML. In an embodiment of the present disclosure, a contact surface of the color film S with the encapsulating sub-pixel structure 10 is larger than a top surface of the light emitting layer EML. In an embodiment of the present disclosure, a left edge of the color film S and a right edge of the color film S are aligned with a left edge of the light emitting layer EML and a right edge of the light emitting layer EML, respectively.

In an embodiment of the present disclosure, the color film S includes an ink layer. In an embodiment of the present disclosure, the color film S is disposed on the light emitting surface of the encapsulating sub-pixel structure 10 by inkjet printing (IJP), in a bid to prevent negative influences of exposure, development, and post-baking processes in the color film process, reduce a thickness of the sub-pixel structure, and enhance the light extraction rate of the sub-pixel structure.

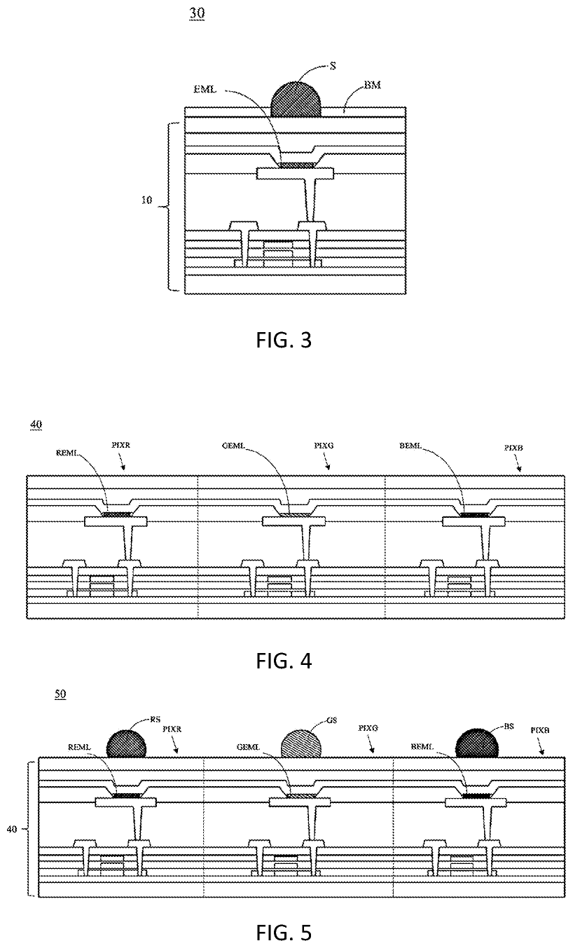

Please refer to FIG. 3, which shows a block diagram showing a sub-pixel structure according to an embodiment of the present disclosure. The difference from FIG. 2 is that the sub-pixel structure 30 further includes a black matrix BM disposed on other portions of the light-emitting surface of the encapsulating sub-pixel structure 10 where the color film S is not disposed, thereby achieving the effect of reducing light leakage and reflectance.

In an embodiment of the present disclosure, the black matrix BM is disposed on the light-emitting surface of the encapsulating sub-pixel structure 10 where the color film S is not disposed by an ink-jet printing (IJP) process.

Please refer to FIG. 4, which is a block diagram showing an encapsulating organic light emitting diode (OLED) display panel according to an embodiment of the present disclosure. The encapsulating OLED display panel 40 includes a red sub-pixel structure PIXR, a green sub-pixel structure PIXG, and a blue sub-pixel structure PIXB, wherein the red sub-pixel structure PIXR includes a red luminescent layer REML configured to emit red light, a green sub-pixel structure PIXG includes a green light-emitting layer GEML configured to emit green light, and the blue sub-pixel structure PIXB includes a blue light-emitting layer BEML configured to emit blue light.

In an embodiment of the present disclosure, the encapsulating OLED display panel 40 disclosed in FIG. 4 is configured by a plurality of encapsulating sub-pixel structures 10 which emit different color lights, however, the encapsulating OLED display panel of the present disclosure is not limited to this.

Please refer to FIG. 5, which is a block diagram showing an organic light emitting diode display panel according to an embodiment of the present disclosure. The OLED display panel 50 includes an encapsulating OLED display panel 40, and a red color film RS disposed on a light emitting surface of the red sub-pixel structure PIXR, wherein the red color film RS has a hemispherical shape, a green color film GS disposed on a light emitting surface of the green sub-pixel structure PIXG, wherein the green color film GS has a hemispherical shape, and a blue color film BS disposed on a light emitting surface of the blue sub-pixel structure PIXB, wherein the blue color film BS has a hemispherical shape, to form an antireflection effect of the lens. In other words, by forming the red color film RS, the green color film GS, and the blue color film BS of microlens arrays (MLA) on the encapsulating OLED display panel 40, the organic light emitting diode display panel 50 can enhance the light extraction rate and effectively reduce reflectance under strong light without disposing the polarizer.

In an embodiment of the present disclosure, the red color film RS, the green color film GS, and the blue color film BS are respectively a pigment-added hemispherical polymer.

In an embodiment of the present disclosure, a position of the red color film RS is aligned with a position of the red luminescent layer REML. In an embodiment of the present disclosure, a position of the green color film GS is aligned with a position of the green luminescent layer GEML. In an embodiment of the present disclosure, a position of the blue color film BS is aligned with a position of the blue luminescent layer BEML.

In an embodiment of the present disclosure, a contact surface of the red color film RS with the encapsulating OLED display panel 40 is larger than a top surface of the red luminescent layer REML. In an embodiment of the present disclosure, a contact surface of the green color film GS with the encapsulating organic light emitting diode display panel 40 is larger than a top surface of the green luminescent layer GEML. In an embodiment of the present disclosure, a contact surface of the blue color film BS with the encapsulating OLED display panel 40 is larger than a top surface of the blue luminescent layer BEML.

In an embodiment of the present disclosure, left and right edges of the red color film RS are aligned with left and right edges of the red luminescent layer REML, respectively. In an embodiment of the present disclosure, left and right edges of the green color film GS are aligned with left and right edges of the green luminescent layer GEML, respectively. In an embodiment of the present disclosure, left and right edges of the blue color film BS are aligned with left and right edges of the blue luminescent layer BEML, respectively.

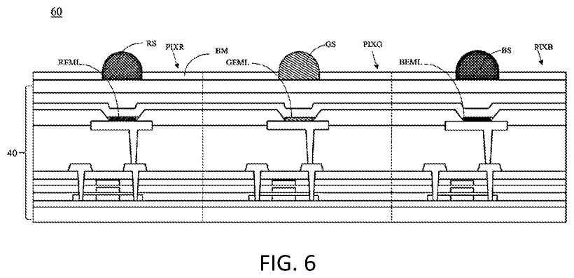

Please refer to FIG. 6, which is a block diagram showing an organic light emitting diode display panel according to an embodiment of the present disclosure, the difference from FIG. 5 is that the OLED display panel 60 further includes a black matrix BM disposed on other portions of the light emitting surface of the encapsulating OLED display panel 40 where the red color film RS, the green color film GS, and the blue color film BS are not disposed, to achieve the effect of reducing light leakage and reflection of the OLED display 60.

In an embodiment of the present disclosure, the red color film RS includes a red ink layer, the green color film GS includes a green ink layer, and the blue color film BS includes a blue ink layer. In an embodiment of the present disclosure, the red color film RS, the green color film GS, and the blue color film BS are disposed on the light emitting surfaces of the red sub-pixel structure PIXR, the green sub-pixel structure PIXG, and the blue sub-pixel structure PIXB by inkjet printing, respectively.

In an embodiment of the present disclosure, the black matrix BM includes a black ink layer. In an embodiment of the present disclosure, the black matrix BM is disposed on other portions of the light emitting surface of the encapsulating OLED display panel 40 where the red color film RS, the green color film GS, and the blue color film BS are not disposed by inkjet printing

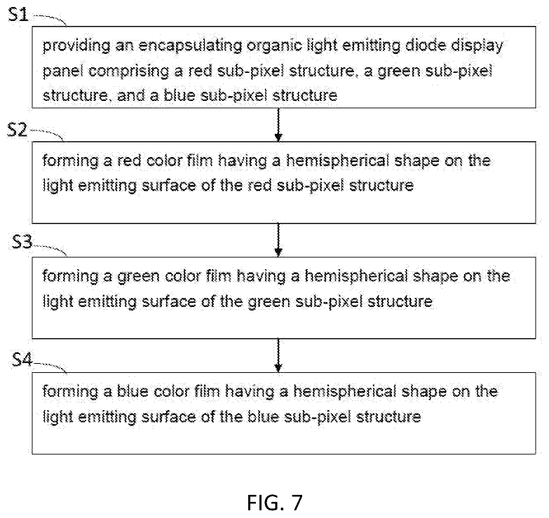

Please refer to FIG. 7, which is a flowchart showing a method of manufacturing an organic light emitting diode display panel according to an embodiment of the present disclosure, wherein the method of manufacturing the organic light emitting diode display panel include:

Step S1: providing an encapsulating organic light emitting diode display panel comprising a red sub-pixel structure, a green sub-pixel structure, and a blue sub-pixel structure.

Step S2: forming a red color film having a hemispherical shape on the light emitting surface of the red sub-pixel structure.

Step S3: forming a green color film having a hemispherical shape on the light emitting surface of the green sub-pixel structure.

Step S4: forming a blue color film having a hemispherical shape on the light emitting surface of the blue sub-pixel structure.

In an embodiment of the present disclosure, the manufacturer can change the order of steps S2, S3, and S4 as needed by the process.

In an embodiment of the present disclosure, after forming the red color film, the green color film, and the blue color film, forming a black matrix on other portions of the light emitting surface of the encapsulating organic light emitting diode display panel where the red color film, the green color film, and the blue color film are not disposed.

In an embodiment of the present disclosure, the red color film, the green color film, and the blue color film are respectively disposed on the light emitting surfaces of the red sub-pixel structure, the green sub-pixel structure, and the blue sub-pixel structure by the inkjet printing method.

In an embodiment of the present disclosure, the black matrix is disposed on other portions of the light emitting surface of the encapsulating organic light emitting diode display panel where the red color film, the green color film, and the blue color film are not disposed by inkjet printing.

The present disclosure provides a sub-pixel structure, an organic light emitting diode display panel, and a manufacturing method thereof, the sub-pixel structure including an encapsulating sub-pixel structure, and a color film disposed on a light emitting surface of the encapsulating sub-pixel structure, wherein the color film has a hemispherical shape, to reduce a thickness of the OLED display panel, enhance the light extraction rate, and prevent the negative influence of the exposure, development, and post-baking processes in the color film manufacturing process, as well as being able to effectively reduce a reflectance of the organic light emitting diode display panel under strong light without disposing a polarizer.

In the above, the present disclosure has been disclosed in the above preferred embodiments, but the preferred embodiments are not intended to limit the present disclosure. A person skilled in the art can make various modifications and refinements without departing from the spirit and scope of the present disclosure, and the scope of the present disclosure is defined by the scope of the claims.

What is claimed is:

1. A sub-pixel structure, comprising:
an encapsulating sub-pixel structure; and
a color film disposed on a light emitting surface of the encapsulating sub-pixel structure, wherein the color film has a hemispherical shape.

2. The sub-pixel structure as claimed in claim 1, further comprising a black matrix disposed on other portions of the light emitting surface of the encapsulating sub-pixel structure where the color film is not disposed.

3. The sub-pixel structure as claimed in claim 1, wherein the color film is a pigment-added hemispherical polymer.

4. The sub-pixel structure as claimed in claim 1, wherein the encapsulating sub-pixel structure is internally provided with a light emitting layer, and a contact surface of the color film with the encapsulating sub-pixel structure is larger than a top surface of the light emitting layer.

5. The sub-pixel structure as claimed in claim 1, wherein the encapsulating sub-pixel structure is internally provided with a light emitting layer, and a left edge of the color film and a right edge of the color film are aligned with a left edge of the light emitting layer and a right edge of the light emitting layer, respectively.

6. The sub-pixel structure as claimed in claim 1, wherein the color film comprises an ink layer.

7. An organic light emitting diode display panel, comprising:
an encapsulating organic light emitting diode display panel, wherein the encapsulating organic light emitting diode panel comprises a red sub-pixel structure, a green sub-pixel structure, and a blue sub-pixel structure;
a red color film disposed on a light emitting surface of the red sub-pixel structure, wherein the red color film has a hemispherical shape;
a green color film disposed on a light emitting surface of the green sub-pixel structure, wherein the green color film has a hemispherical shape; and
a blue color film disposed on a light emitting surface of the blue sub-pixel structure, wherein the blue color film has a hemispherical shape.

8. The organic light emitting diode display panel as claimed in claim 7, wherein the red sub-pixel structure comprises a red luminescent layer configured to emit red light, the green sub-pixel structure comprises a green luminescent layer configured to emit green light, and the blue sub-pixel structure comprises a blue luminescent layer configured to emit blue light.

9. The organic light emitting diode display panel as claimed in claim 8, wherein a position of the red color film is aligned with a position of the red luminescent layer, a position of the green color film is aligned with a position of the green luminescent layer, and a position of the blue color film is aligned with a position of the blue luminescent layer.

10. The organic light emitting diode display panel as claimed in claim 8, wherein a contact surface of the red color film with the encapsulating organic light emitting diode display panel is larger than a top surface of the red luminescent layer.

11. The organic light emitting diode display panel as claimed in claim 8, wherein a contact surface of the green color film with the encapsulating organic light emitting diode display panel is larger than a top surface of the green luminescent layer.

12. The organic light emitting diode display panel as claimed in claim 8, wherein a contact surface of the blue color film with the encapsulating organic light emitting diode display panel is larger than a top surface of the blue luminescent layer.

13. The organic light emitting diode display panel as claimed in claim 7, wherein the red color film, the green color film, and the blue color film are respectively pigment-added hemispherical polymers.

14. The organic light emitting diode display panel as claimed in claim 7, further comprising a black matrix disposed on other portions of the light emitting surface of the encapsulating organic light emitting diode display panel where the red color film, the green color film, and the blue color film are not disposed.

15. The organic light emitting diode display panel as claimed in claim 7, wherein the red color film comprises a red ink layer, the green color film comprises a green ink layer, and the blue color film comprises a blue ink layer.

16. The organic light emitting diode display panel as claimed in claim 7, wherein a black matrix comprises a black ink layer.

17. A method of manufacturing an organic light emitting diode display panel, comprising:
providing an encapsulating organic light emitting diode display panel comprising a red sub-pixel structure, a green sub-pixel structure, and a blue sub-pixel structure;
forming a red color film having a hemispherical shape on a light emitting surface of the red sub-pixel structure;
forming a green color film having a hemispherical shape on a light emitting surface of the green sub-pixel structure; and
forming a blue color film having a hemispherical shape on a light emitting surface of the blue sub-pixel structure.

18. The method of manufacturing the organic light emitting diode display panel as claimed in claim 17, wherein after forming the red color film, the green color film, and the blue color film, further forming a black matrix on other portions of the light emitting surface of the encapsulating organic light emitting diode display panel where the red color film, the green color film, and the blue color film are not disposed.

19. The method of manufacturing the organic light emitting diode display panel as claimed in claim 17, wherein the red color film, the green color film, and the blue color film are disposed on the light emitting surface of the red sub-pixel structure, the light emitting surface of the green sub-pixel structure, and the light emitting surface of the blue sub-pixel structure, respectively, by inkjet printing.

20. The method of manufacturing the organic light emitting diode display panel as claimed in claim 18, wherein the black matrix is disposed on other portions of the light emitting surface of the encapsulating organic light emitting diode display panel where the red color film, the green color film, and the blue color film are not disposed by inkjet printing.
